(19) United States
(12) Patent Application Publication
(10) Pub. No.: US 2026/0227447 A1
(43) Pub. Date: Aug. 6, 2026

(54) SMART MONITORING TO AUTONOMOUSLY TRACK BATTERY RELAXATION IN wBMS

(71) Applicant: Analog Devices, Inc., Wilmington, MA (US)

(72) Inventor: Jackie HUI, Allen, TX (US)

(21) Appl. No.: 19/149,808

(22) PCT Filed: Mar. 7, 2024
(86) PCT No.: PCT/US2024/018973

§ 371 Date: Jul. 21, 2025

Related U.S. Application Data
(60) Provisional application No. 63/489,612, filed on Mar. 10, 2023.

(51) Int. Cl. G01R 31/3835; G01R 31/374; H01M 10/42; H01M 10/48

(52) U.S. Cl. CPC G01R 31/3835; G01R 31/374; H01M 10/425; H01M 10/482; H01M 2010/4271

(57) ABSTRACT

A method of autonomously capturing open cell voltage (OCV) trends of a battery, including receiving, by a radio node of the battery and from a radio manager associated with a controller, a command to begin an OCV monitoring process, recording an initial OCV measurement, and determining if a period measurement interval has been reached and, if a period measurement interval has been reached, taking an OCV measurement and determining if an OCV rate of change between OCV measurements is less than a configured threshold.

### PRIORITY DATA AND RELATED APPLICATION(S)

This patent application claims priority to U.S. Provisional Application No. 63/489,612, entitled SMART MONITORING TO AUTONOMOUSLY TRACK BATTERY RELAXATION IN wBMS, filed on Mar. 10, 2023, which is incorporated by reference in its entirety.

### BACKGROUND

### Technical Field

The present disclosure relates generally to battery monitoring systems, and more particularly, to battery monitoring in battery management systems (BMS) in electric vehicle environments, and particularly to wireless battery monitoring systems.

### Introduction

When electric vehicles transition from a driving or charging state to an off state where the key has turned the systems off such that they are no longer drawing energy from the battery (a “key-off state”), a traction battery of the electric vehicle enters a battery relaxation phase. Typically, measuring open circuit voltage (OCV) during a battery relaxation phase in current BMS system architecture, a host controller of the battery is required to be in an active state. This undermines and ultimately forfeits any benefits of minimizing 12V battery power consumption during the key-off state, since the active state of the host controller is drawing energy from the 12V battery. No known continuous OCV trend monitoring applications without host controller involvement currently exist for electric vehicle batteries.

There exists a need for further improvements in vehicle battery monitoring technology. These improvements may also be applicable to other battery monitoring technologies and the standards that employ these technologies.

### SUMMARY

The following presents a simplified summary of one or more aspects in order to provide a basic understanding of such aspects. This summary is not an extensive overview of all contemplated aspects and is intended to neither identify key or critical elements of all aspects nor delineate the scope of any or all aspects. Its sole purpose is to present some concepts of one or more aspects in a simplified form as a prelude to the more detailed description that is presented later.

Disclosed herein are systems and methods for tracking battery cells and collecting data when a battery has entered a relaxation phase, while a host application and/or controller may be absent, suspended, or non-operational. Smart monitoring functionality can save the OCV trend data and battery relaxation time in the monitoring electronics. Then, the host controller can read out, access, or otherwise receive the OCV trend data when the system is back online. Additionally or alternatively, smart monitoring functionality can pair with fault or anomaly detection algorithms which allows the monitoring system to proactively send one or more alarm signals to wake up the host controller. For example, the monitoring system can send an alarm to a host application/or controller to collect measurement data when preconfigured alarm thresholds are reached. It can also pair with one or more battery insight algorithms to monitor a battery cell status after a test signal stimulus or be used as a relaxation detector before injecting test signal stimulus for use with battery insight algorithm. Data captured may include and/or relate to cell voltage trends, time to reach certain voltage stability stages of the battery cell during relaxation, cell temperature trends, etc. Data can be stored in non-transitory computer readable memory in a radio node and/or controller, and offloaded to an overall system controller at key-on.

A relaxation phase of a battery cell exists when a charge or discharge current is removed from the battery cell and the battery cell is at rest. During this period, the battery cell voltage is known to exhibit an initial rapid change in battery cell voltage that gradually changes over the course of many hours to reach an equalized level.

Adjusting a battery data monitoring interval autonomously (i.e., without a main battery management system controller's involvement) can be accomplished by monitoring a battery cell voltage rate of change. This can be beneficial in identifying different stages in a relaxation period until the battery cell is in a full relaxation mode, is at a full relaxation level, or is otherwise fully relaxed. Storing battery cell data captured during this period as raw data can be useful in generating battery health insights.

Monitoring and tracking OCV values and trends during a vehicle operation phase and during a battery testing phase can require different considerations, and both are described herein.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

FIG. 1A is a diagram illustrating an example of a relaxation period after a charging event in accordance with an aspect of the present invention.

FIG. 1B is a diagram illustrating an example of a relaxation period after a discharging event in accordance with an aspect of the present invention.

FIG. 2 is a diagram illustrating an example of scalable smart monitoring intervals in a battery relaxation phase in accordance with an aspect of the present invention.

FIG. 3 is a diagram illustrating an example of a wired battery monitoring system architecture in accordance with an aspect of the present invention.

FIG. 4A is a diagram illustrating an example of a wireless battery monitoring system architecture in accordance with an aspect of the present invention.

FIG. 4B is a diagram illustrating an example of a radio node architecture in accordance with an aspect of the present invention.

FIG. 5 is a diagram illustrating an example of monitoring open circuit voltage and reading points in accordance with an aspect of the present invention.

FIG. 6 is a diagram illustrating an example of blocks for monitoring open circuit voltage in accordance with an aspect of the present invention.

FIG. 7 is a flowchart illustrating an example a method of monitoring open circuit voltage in accordance with an aspect of the present invention.

FIG. 8 is a diagram illustrating an example of monitoring open circuit voltage and reading points in accordance with an aspect of the present invention.

FIG. 9 is a flowchart illustrating an example of a method of monitoring open circuit voltage in accordance with an aspect of the present invention.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Several aspects of electronic systems will now be presented with reference to various apparatuses and methods. These apparatuses and methods will be described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more example aspects, the functions described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can comprise a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer executable code in the form of instructions or data structures that can be accessed by a computer.

Electric Vehicle traction batteries can include one or more battery cell stack including one or more battery cells. In various aspects and for various different vehicles and applications, one, several, or many battery cells can be included in the one or more battery cell stacks.

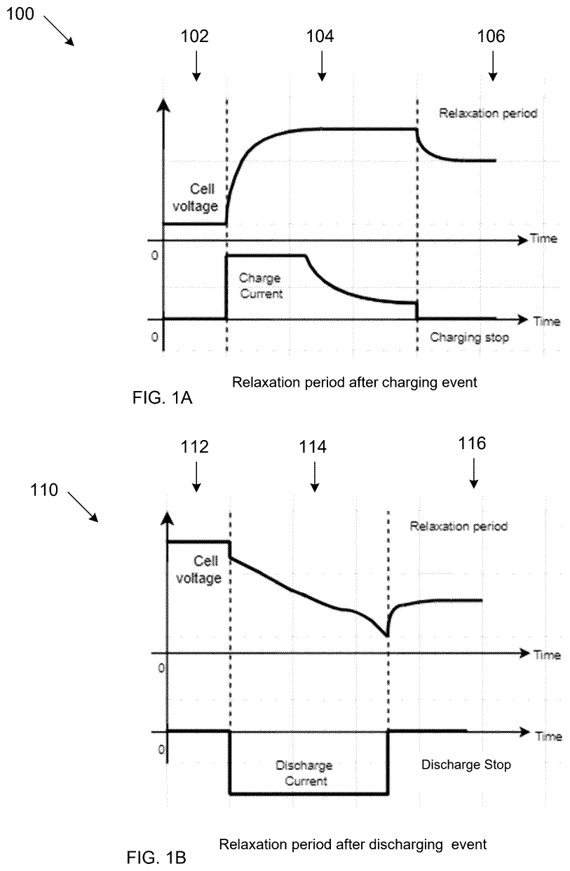

As described above, at an onset of a cell relaxation period, battery cell voltage is known to exhibit an initial rapid change in battery cell voltage that gradually changes over the course of many hours to reach an equalized level. FIGS. 1A and 1B are diagrams showing different relaxation characteristics for different relaxation periods.

FIG. 1A is a diagram 100 illustrating an example of a relaxation period after a charging event.

As shown, there may be three general phases associated with a charging event. A first phase 102 can be a discharged battery phase and/or cell resting condition. Here, the battery cell voltage can be low and/or flat, and the charge current can be zero, since charging has not yet begun. Once charging begins, a second phase 104 can include a rapid charging period followed by a generally high voltage. A high charge current can be associated with the rapid charging period and a rapidly declining and then generally decreasing charge current period can occur in association with the generally high voltage. To elaborate, second phase 104 can be a simple Constant Current-Constant Voltage (CC-CV) charging profile. During a constant current charging phase, a high charging current is applied and cell voltage increases accordingly. As the cell voltage reaches a target charge voltage, the charging activity enters a constant voltage phase, wherein the cell voltage is maintained at a target voltage while the charging current is gradually reduced. Charge termination can occur and be detected when the charging current is reduced to a low charge rate (C-rate) such as C/10. Different and more complex charging profile and charge termination methods can be applied as well. This disclosure does not constrain the length of a charging event (i.e., there is no need to have a full charge cycle for the teachings herein to apply) or a type of charging profile. Once charging has stopped, a third phase 106 can be a relaxation period. A relaxation period can include rapidly declining battery cell voltage followed by a leveling out at a relaxed cell voltage level. Charge current is zero when charging has ceased. In some instances, a first phase can be a discharging event, wherein the cell voltage is decreasing.

FIG. 1B is a diagram 110 illustrating an example of a relaxation period after a discharging event.

As shown, there may be three general phases associated with a discharging event. A first phase 112 can be a charged battery phase and/or cell resting condition where a cell is at rest with a high cell voltage. Here, the battery cell voltage can be at an initial battery cell voltage level and the discharge current can be zero, since discharging has not yet begun. The battery cell can be at a relaxed level in the first phase, from a prior charging cycle. Once discharging begins, a second phase 114 can include a generally linear discharging period, or may have variations, depending on the load being powered by the battery cell, until discharging has been complete, or the load is removed. A discharge current can be associated with the discharge voltage, and in the case of a constant discharge with a fixed or unchanging load, a discharge current level can be constant and negative or below zero, since the battery is being discharged to power the load. In various aspects a discharge current is a negative current and the cell voltage drops according to the discharge current. The larger the load, the fast the drop of the cell voltage. Phase 114 shows a constant discharge current. The cell voltage drop characteristics with a constant discharge current are different in various instances because they are greatly influenced by and/or dependent on cell chemistry. In various aspects a full discharge curve is non-linear (although it can be linear in certain cell voltage range, and then flat across a different voltage range and a rapid drop at close to the end of a cell's min cell voltage). FIG. 1B shows a cell voltage decreasing with a constant discharge current, which represents a discharging event. Once discharging has stopped, a third phase 116 can be a relaxation period. A relaxation period after a discharging event can include a rapidly increasing battery cell voltage followed by a swift leveling out at a relaxed cell voltage level. A discharge current level is zero when discharging has ceased.

Relaxation followed by a charge event generally occurs according to a particular pattern. Cell relaxation is generally associated with a rapid change of cell voltage (i.e., a sharp drop or sharp increase in cell voltage depends on whether the onset of relaxation is followed by a charging or discharging event), and then the cell voltage slowly levels out. Fully discharging a cell is not required. A short discharge period, as compared to a long discharge period, will result in a relaxation behavior, but a cell will generally level out faster in such instances. The level of a discharging current also affects the time a cell to reach full relaxation. However, the relaxation behavior of the cell is similar-a sharp voltage change occurs initially and then a slower leveling out of the voltage follows.

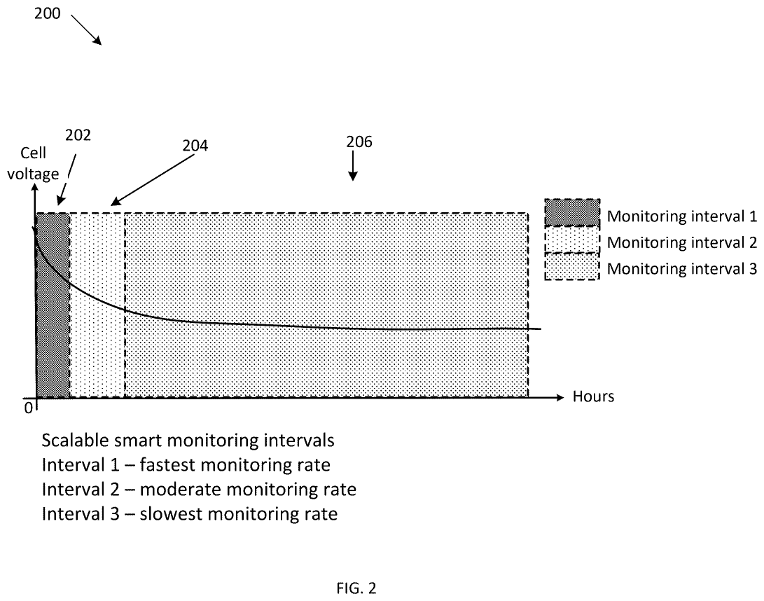

FIG. 2 is a diagram 200 illustrating an example of a scalable smart monitoring intervals in a battery relaxation after a charge event. Diagram 200 generally depicts an example relaxation phase after a charge event, which is characterized by a sharp initial drop in cell voltage. However, if a relaxation period occurs after a discharge event, the cell voltage will exhibit a sharp increase instead. A first monitoring interval 202 can occur at a highest cell voltage and can include more frequent monitoring intervals that corresponds to a fast rate of change in cell voltage change. For example, this highest cell voltage can occur immediately after a battery charging event. A second monitoring interval 204 can include a gradually declining rate of battery relaxation that corresponds to a moderate rate of cell voltage change. A third monitoring interval 206 can include a slowly declining rate of battery relaxation that corresponds to a low rate of cell voltage change.

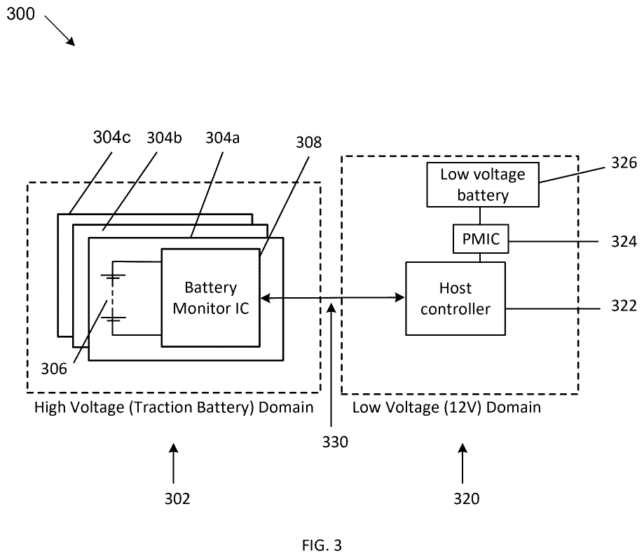

FIG. 3 is a diagram 300 illustrating an example of a wired battery monitoring system architecture. As shown, a wired battery monitoring system architecture can generally include a high voltage domain 302 and a low voltage domain 320 that are communicatively coupled by one or more isolated communication wires 330.

In some aspects, the high voltage domain 302 can be associated with a battery (e.g., a traction battery, which may have a voltage of 900V in some aspects) of an electric vehicle. The high voltage domain 302 can include a battery cell stack including one or more battery cells. Shown are three battery cell stacks 304a, 304b, 304c (also referred to as battery modules) in a battery pack Each of the battery cells (e.g., battery cell stack 304a) can include a battery 306 that is coupled with a battery monitor integrated circuit (BMIC) 308.

In some aspects, a battery pack is a battery cell stack including multiple battery cells connected in series. The battery cells in this cell stack are grouped in multiple groups. Each group is referred as a battery cell module. Each battery cell module has its electronics (e.g., battery cell monitor(s)) for monitoring. It should be understood that there are different module arrangements of battery packs in various aspects and the electronics can have different architectures with respect to such cell module arrangements.

In some aspects, the low voltage domain 320 can be associated with a low voltage battery of an electric vehicle, such as low voltage battery 326 (e.g., a 12V battery). The low voltage domain 320 can include a host controller 322 that is coupled with a power management integrated circuit (PMIC) 324. The PMIC 324 can be coupled with the low voltage battery 326. As shown, the PMIC is transforming the 12V to a voltage level that is suitable to power the host controller. In other words, the host controller is powered by the 12V battery through the PMIC.

The host controller 322 of the low voltage domain 320 is communicatively coupled with the one or more of the BMIC 308s via the one or more isolated communication wires 330.

In a vehicle operation phase, collecting OCV data for a traction battery (e.g., a Lithium-ion (Li-ion) battery) can be useful during a battery relaxation period. As an example, collecting data regarding OCV trends during relaxation or a time to relaxation from an initial relaxation state to a stable OCV state can be useful. For example, this data can be used to detect battery anomalies at an early stage for further analysis and mitigation and/or replacement of the battery.

Without the systems, apparatuses, and methods described in the aspects herein, in a vehicle operation phase a host controller would be required to take OCV measurements immediately before a high voltage contactor is close to the battery cell or battery cell stack when a vehicle is about to transition from a key-off phase to a key-on phase. However, in any given instance, this measurement may occur at any point in a relaxation cycle but is likely to occur when battery cells are far into a stable relaxation phase if the electric vehicle has been turned off for an appreciable amount of time. In other words, unless an electric vehicle has been at a key-off phase for a significant amount of time (e.g., on the order of hours), the quality of an OCV measurement is uncertain, as such measurement may occur at any point in relaxation phase. This is one problem with the approach of measuring OCV only at a time immediately prior to starting up the vehicle. A host controller may wake up periodically during a key-off phase to take OCV measurements as part of a vehicle key-off monitoring scheme. This allows the host controller to capture the cell relaxation trend. The cell relaxation trend not only provides additional data for possible cell status analysis but also enables the host controller to assess the quality of the OCV readings. However, this approach requires waking up the host controller, which detrimentally incurs 12V battery power consumption.

In a typical automotive electric vehicle wired BMS system as shown in FIG. 3, the battery cell stacks 304a, 304b, 304c are monitored by a group of the BMIC 308s coupled together, for instance, in a daisy chain. The BMIC 308s are used to measure battery cell data, such as battery cell voltages and battery temperature (e.g., overall, locally in one or more locations, of particular components such as connectors, bus bars, or combinations thereof). The BMIC 308s are slave devices that are controlled by the host controller 322 (i.e., the master) to initiate any data measurement using coupled sensors (not shown).

To collect OCV measurements, an electric vehicle will generally be in a key-off state without any battery charging activity occurring. In this key-off state, it is highly desirable to preserve, protect, and/or maintain a capacity of the low voltage battery 326 as much as possible, since the low voltage battery 326 can provide vital functionality such as starter motor power and/or other critical systems.

In a battery cell or battery cell stack testing phase, a manufacturer and/or third party may perform one or more battery charging and discharging cycles, or apply other test signal stimulus, in order to test the battery cells.

This collection of OCV measurements and/or trends of battery cell voltage changes after charging and discharging cycles and/or other test signal stimulus can provide useful data measurements which can be used for early anomaly detection and analysis.

In the battery cell or battery cell stack testing phase, a battery cell or battery cell stack is not integrated and/or installed with a final BMS system yet (i.e., in an electric vehicle for use by drivers in regular operation), and a test controller and/or test station can act as a master to controller a BMIC for such collection of OCV measurements and/or trends of battery cell voltage changes after charging and discharging cycles and/or other test signal stimulus.

To track OCV trends after a charging and discharging cycle and/or other test signal stimulus is applied, the battery cell or battery cell stack will need to be communicatively coupled with the test station. Depending on the type of stimulus, tracking OCV trends from an initial relaxation state to a final, stable relaxation state may require hours for completion. Therefore, it may not be practical in a manufacturing phase to wait in real-time, since this waiting would hold up the test station and serve as a bottleneck, impacting production throughput.

An alternative solution available according to various aspects herein can be disconnecting the battery cell or battery cell stack from a test station after a test stimulus is applied, setting the battery cell or battery cell stack aside, and waiting for a fixed amount of time before reconnecting the battery cell or battery cell stack to measure OCV. This approach allows a manufacturer and/or third-party to collect OCV measurements at an expected relaxation state. However, if the OCV measurement is outside of an expected range, it would be useful to have voltage trend data over the relaxation period to provide enhanced anomaly analysis before reconnecting to a test station to measure OCV.

In a battery cell or battery cell stack manufacturing and/or third-party testing phase, a manufacturer or third-party tester is likely to perform and/or examine at a charging and discharging cycle or test signal stimulus as one test step and perform OCV measurement in a different step. However, this approach cannot accurately or reliably track OCV trends over time. While the testing step could occur on the test floor, the measurement step could occur after transporting the battery cell or battery stack to the electric vehicle manufacturer for installation in an electric vehicle or in storing and/or cataloging inventory.

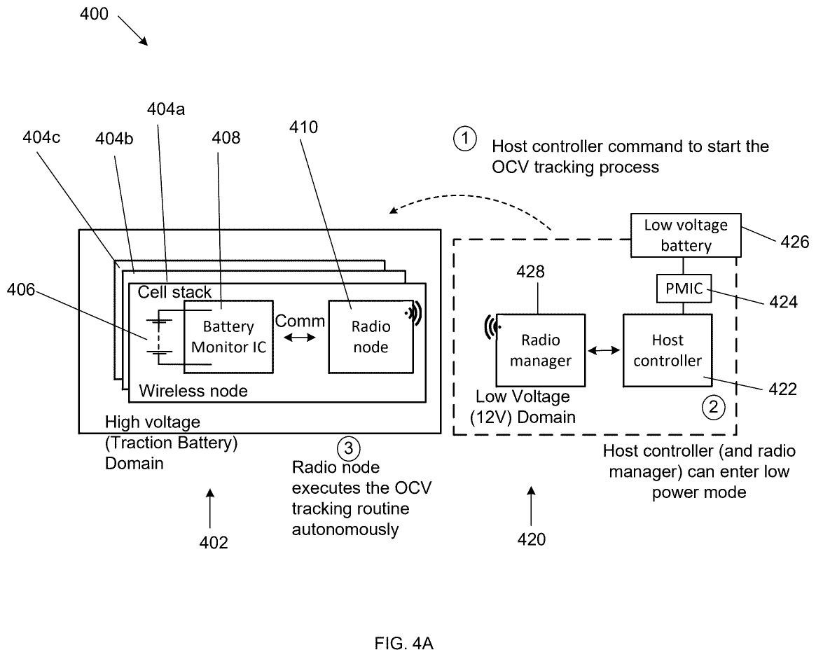

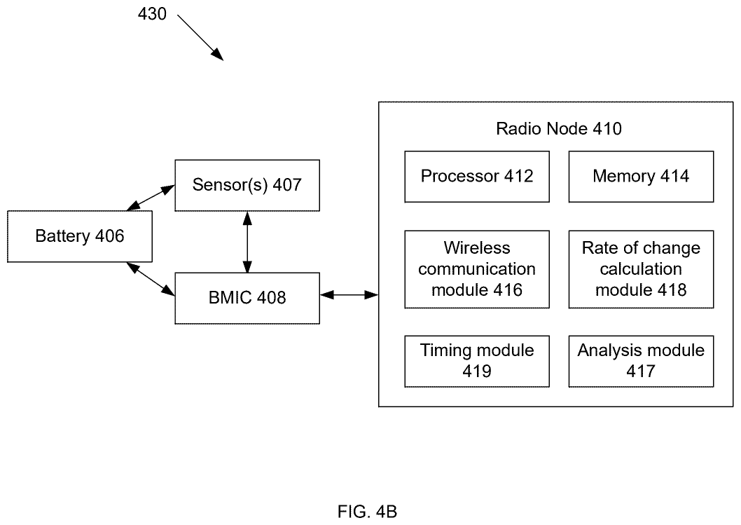

FIG. 4A is a diagram 400 illustrating an example of a wireless battery monitoring system architecture. FIG. 4B is a diagram 430 illustrating an example of a radio node 410 architecture.

As shown in FIG. 4A, a wireless battery monitoring system architecture can generally include a high voltage domain 402 and a low voltage domain 420 that are communicatively coupled via one or more wireless links.

In some aspects, the high voltage domain 402 can be associated with a traction battery of an electric vehicle. The high voltage domain 402 can include a battery cell stack including one or more battery cells. Shown are three battery cell stacks 404a, 404b, 404c (also referred to as battery modules) in a battery cell pack, although more or fewer battery cell stacks can be included in a battery cell pack in different aspects. Each of the battery modules (e.g., battery cell stack 404a) can include one or more battery cell 406 that is coupled with a BMIC 408. The BMIC 408 is communicatively coupled with a radio node 410 (e.g., wirelessly or wired in various aspects).

In some aspects, the low voltage domain 420 can be associated with a low voltage battery of an electric vehicle, such as a low voltage battery 426 (e.g., a 12V battery). The low voltage domain 420 can include a host controller 422 that is coupled with a power management integrated circuit (PMIC) 424. The PMIC 424 can be coupled with low voltage battery 426. The host controller 422 can be coupled with a radio manager 428.

The radio manager 428 of the low voltage domain 420 can be communicatively coupled with the one or more radio node 410 via one or more wireless links or connections.

In various aspects, a wireless BMS architecture as shown in FIG. 4A includes radio nodes 410 acting as a local master to respective coupled BMICs 408. As shown in FIG. 4B, a radio node 410 can include one or more processors 412, one or more memory 414, a wireless communication module 416, an analysis module 417, a rate of change calculation module 418, a timing module 419, and others. The radio node 410 can be coupled with one or more BMIC 408. Each of the one or more BMIC 408 can be coupled with one or more sensors 407 (e.g., one or more pressure sensor, external memory, temperature sensor, and/or others). The BMIC 408 also be coupled with a battery 406. The sensor(s) 407 can be coupled with the battery 406.

When a host application needs to start OCV relaxation monitoring, by monitoring an OCV trend over a relaxation period, the host application can issue a command to start a predefined monitoring process, stored in non-transitory computer readable memory (e.g., onboard or coupled with the BMIC 408 and/or the radio node 410) and executed by one or more processors 412 of the radio node 410.

In a vehicle operation phase, when the vehicle enters a key-off state, the BMS host controller 422 can issue a command to start an OCV monitoring process to the radio node 410 that is transmitted over the wireless link and received by the wireless communication module 416 of the radio node 410 via the radio manager 428. The host controller 422 can then put itself into a low power state.

In a battery cell or battery cell stack manufacturing and/or testing phase, after a charging and discharging cycle and/or test stimulus is applied, a test station can issue a command to the radio node 410 to start an OCV monitoring process and the module/pack be removed from the test station afterward.

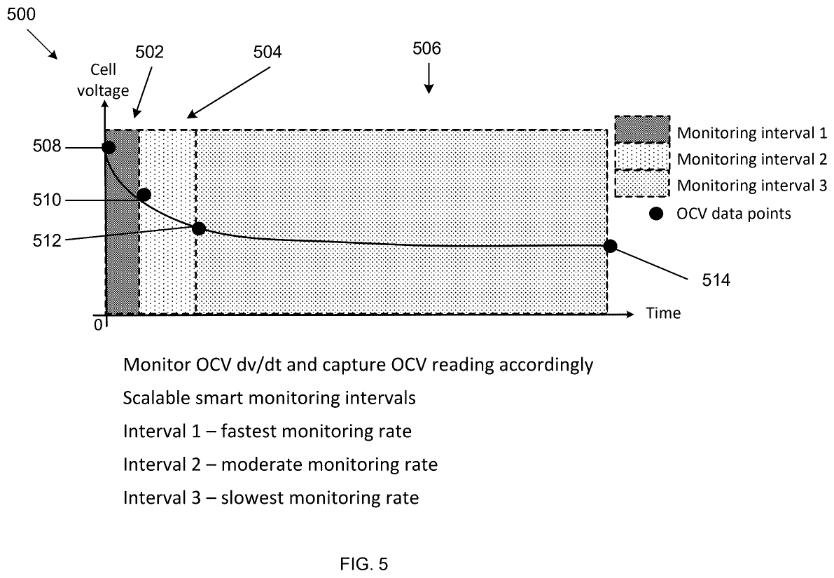

FIG. 5 is a diagram 500 illustrating an example of monitoring open circuit voltage and reading points.

As shown, a first monitoring interval 502 can occur at a highest rate of voltage change and can include a highest rate of battery relaxation that corresponds to a fast rate of cell voltage change. For example, this highest cell voltage can occur immediately after a battery charging event. A second monitoring interval 504 can include a gradually declining rate of battery relaxation that corresponds to a moderate rate of cell voltage change. A third monitoring interval 506 can include a slowly declining rate of battery relaxation that corresponds to a low rate of cell voltage change.

A first OCV data point 508 can be measured by a BMIC 408 at the beginning of the first monitoring interval 502 and can be a highest cell voltage value. A second OCV data point 510 can be measured by a BMIC 408 and can occur at a transition from first monitoring interval 502 to second monitoring interval 504. A third OCV data point 512 can be measured by a BMIC 408 and can occur at a transition from second monitoring interval 504 to third monitoring interval 506. A fourth OCV data point 514 can be measured by a BMIC 408 and can occur at a fully relaxed state.

In various aspects, OCV monitoring intervals can be pre-configured by a user. The user can pre-define a set of OCV rates of change (dv/dt) that correspond to each monitoring interval 502, 504, 506. In some aspects, possible monitoring methods include monitoring OCV dv/dt and capturing OCV reading measurements as the dv/dt differs from the pre-configured setting.

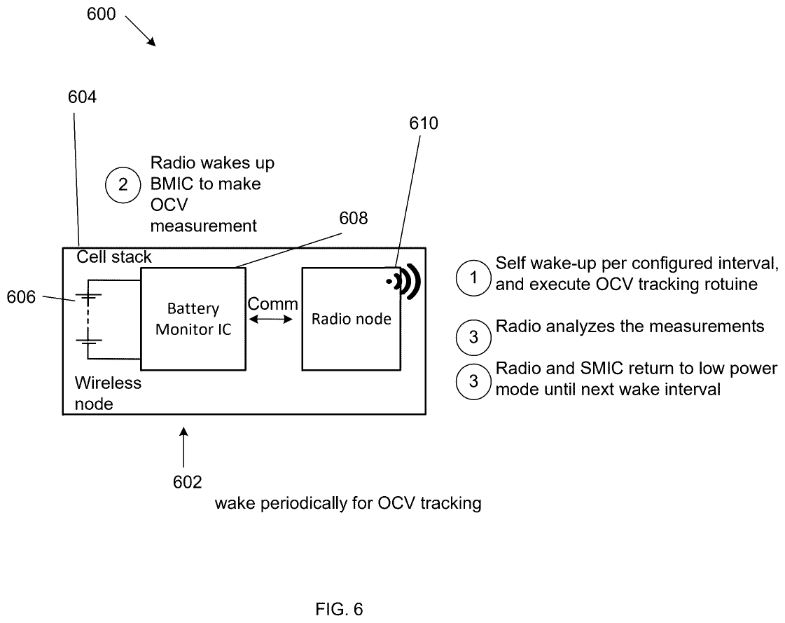

FIG. 6 is a diagram 600 illustrating an example of blocks for monitoring open circuit voltage.

As shown, a wireless battery monitoring system architecture can generally include a wireless node 602 and that can be communicatively coupled with a low voltage domain (not shown), via one or more wireless links.

In some aspects, the wireless node 602 can be associated with a traction battery of an electric vehicle. The wireless node 602 can include a battery cell stack 604 including one or more battery cells 606. Each battery cell 606 that is coupled with a BMIC 608. The BMIC 608 is communicatively coupled with a radio node 610 (see FIG. 4B and associated description for an example of radio node architecture according to some aspects, which will be referenced below).

In some aspects, monitoring routines and configurations can be implemented in a radio node 610 (e.g., analogous to radio node 410 of FIG. 4B). At a predefined and/or expected time to start or during a monitoring interval or transition between monitoring intervals, a processor (e.g., a processor 412) of the radio node 610 can wake up the radio node 610 according to a pre-configured interval and execute an OCV tracking routine, whereby the processor wakes up the BMIC 608 (e.g., analogous to BMIC 408 of FIG. 4B) so that the BMIC 608 can make battery cell voltage measurements. The radio node 610 can then perform calculations (e.g., via a processor 412 and/or a rate of change calculation module 418) and analyze the measurements as needed (e.g., via the processor 412 and an analysis module 417) and put the BMIC 608 back to sleep until a next predefined and/or expected time.

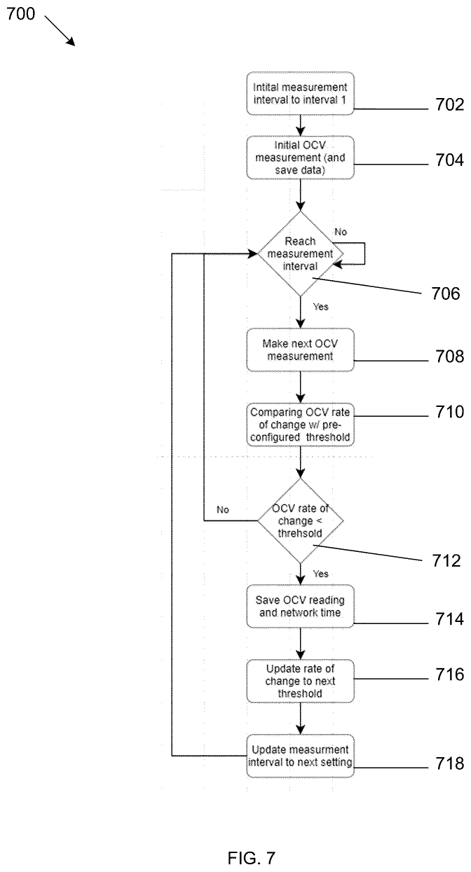

The radio node 610 can then run through a monitoring flow (e.g., as shown in the example in FIG. 7), and capture OCV measurement trends during relaxation for measurements of the battery 606 by the BMIC (e.g., BMIC 408 of FIG. 4B). A pre-defined timeout using a timing module (e.g., timing module 419 of FIG. 4B) of a monitoring routine can be implemented as a way to capture the last OCV measurements when the battery 606 enters full relaxation which dv/dt no long have significant change over time.

FIG. 7 is a flowchart 700 illustrating an example of blocks in monitoring open circuit voltage.

As shown at a first block 702 an initial measurement interval can be set to 1 second (e.g., for a timing module 419) by a processor (e.g., the processor 412). At a second block 704 the processor can cause an initial OCV measurement to be captured, made, or taken by a BMIC (e.g., BMIC 408) and the data value can be saved in memory (e.g., the memory 414). At a third block 706 the processor, via a timing module (e.g., the timing module 419) can determine whether a measurement interval has been reached. For example, a time threshold based on a time elapsed, set time, timer, or otherwise can be used. If the processor determines that the next measurement interval has been reached, a fourth block 708 can be performed. Otherwise, the third block 706 can be performed again after a preset amount of time via the timing module. This process at the third block 706 can be repeated by the processor and the timing module until measurement interval is reached. At a fourth block 708 the processor can perform, capture, make, or take a next OCV measurement via the sensor and saving the data value can occur in memory. A fifth block 710 can include comparing an OCV rate of change with a pre-configured OCV rate of change threshold value via a rate of change calculation module (e.g., the rate of change calculation module 418). A sixth block 712 can include the processor determining whether the OCV rate of change is less than the pre-configured OCV rate of change threshold value stored in memory. If the processor determines OCV rate of change is not less than the pre-configured OCV rate of change threshold value, then the process can return to the block 706. If the processor determines the OCV rate of change is less than the pre-configured OCV rate of change threshold value, then in a block 714 the OCV reading and a network time (e.g., from the timing module 419) can be saved in memory (e.g., in memory 414). Once the OCV reading and the network time are saved in memory, in a block 716 the pre-configured OCV rate of change threshold value can be updated by the processor to a next pre-configured OCV rate of change threshold. After updating the pre-configured OCV rate of change threshold value, in block 718 the measurement interval can be updated by the processor to a next measurement interval. Once the measurement interval is updated to a next measurement interval by the processor, the process can return to block 706.

If a finer resolution of OCV capture is more desirable, an alternative approach can be configured a dv/dt target, and the number of data saved point required. This approach can apply at the beginning of the battery relaxation where the OCV dv/dt change more rapidly.

In addition to OCV capture, cell temperature change may also be useful information during relaxation. This monitoring proposal can also be used to capture cell temperature alongside the OCV measurements.

In vehicle operation phase, the host controller can initiate a read at key-on to read back all the saved data as part of the BMS system initialization. This will free up the memory space for the next relaxation monitoring and data capturing at the wireless node.

Similar approach can be implemented in battery module/pack manufacturing phase as well, in which a test controller can read back the saved data when the module/pack under-test is connected to a test system again.

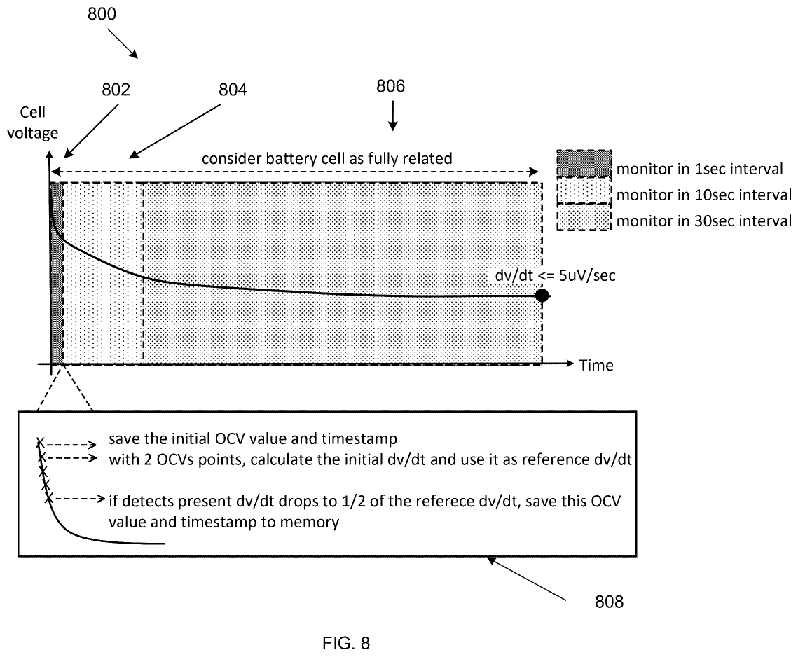

FIG. 8 is a diagram 800 illustrating an example of monitoring open circuit voltage and reading points.

As shown, in various aspects, an OCV relaxation curve can generally be defined as three regions: a first region 802, a second region 804, and a third region 806.

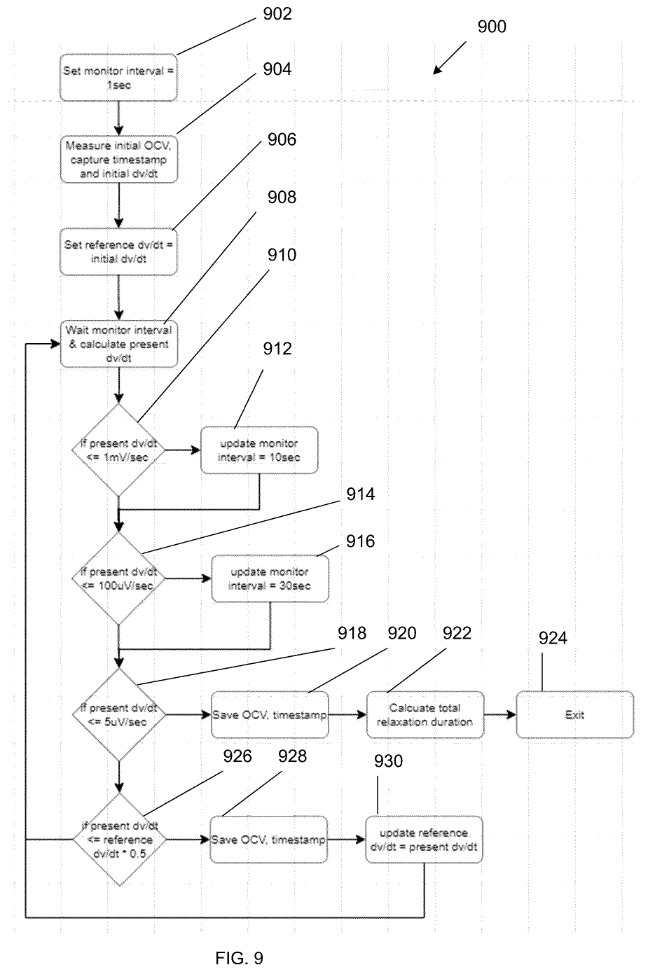

In order to monitor where a battery relaxation may be along an OCV relaxation curve, a measurement interval can be set for each region (See FIG. 9 and associated description for further information on setting intervals and monitoring). The first region 802 can include OCV changes in the highest and/or fastest rate, and the measurement interval can be set to a smallest interval (e.g., one second). The second region 804 can include OCV changes in a slower rate, and the measurement interval can be set to a middle interval (e.g., ten seconds). The third region 806 can include OCV changes in the slowest rate, and the measurement interval can be set to a largest interval (e.g., thirty seconds).

According to various aspects, systems, apparatuses, and methods can optimize the storage space in local memory by saving data measurements only when an OCV rate of change (dv/dt) drops by half, as compared to a reference and/or current and/or previous OCV rate of change (dv/dt). A dv/dt rate can be defined as a battery cell in fully relaxed state. For example, a dv/dt rate can be defined as less than or equal to 5 uV/s.

As shown in inset 808 (and further shown and described with respect to FIG. 9), measurements can be taken along a relaxation curve. An initial OCV value can be measured and stored with an associated timestamp. A next OCV value can provide an additional data point with which an initial dv/dt can be calculated and used as a reference dv/dt value. As time progresses, if a present dv/dt is measured that is less than half of the reference dv/dt value, an OCV value at such point can be stored along with a timestamp in memory.

FIG. 9 is a flowchart 900 illustrating an example of a method of monitoring open circuit voltage.

As shown, at a block 902 a processor (e.g., the processor 412) can set a monitoring interval value (e.g., 1 second) via a timing module (e.g., the timing module 419). At a block 904 can include the processor causing the BMIC to perform, capture, make, or take an initial OCV measurement by BMIC 408 and the processor can save the data value, a timestamp, and an initial value of dv/dt in a memory (e.g., the memory 414). At block 906 the processor can set reference dv/dt to the initial value of dv/dt. At block 908 a timing module (e.g., the timing module 419) can cause the radio node to wait for the amount of time set as the monitoring interval in block 902 and the processor can calculate a current or present dv/dt via the rate of change calculation module 418.

Using the latest calculated dv/dt from block 908, this dv/dt is then passing through block 910, 914, and 918.

Block 910 checks if the latest calculated dv/dt meets the criteria to transition from region 802 to 804 using a slower dv/dt threshold (e.g., 1 mV/sec). If the last calculated dv/dt meets this condition or threshold, the monitoring interval is updated to a longer interval (e.g., 10 seconds).

Block 914 checks if the latest calculated dv/dt meets the criteria to transition from region 804 to 806 using an even slower dv/dt threshold (e.g., 100 uV/sec). If the last calculated dv/dt meets this condition or threshold, the monitoring interval is updated to the slowest interval (e.g., 30 seconds).

Block 918 checks if the latest calculated dv/dt is at a fully relaxation state using minimal rate of OCV change threshold (e.g., 5 uV/sec). If the last calculated dv/dt meets this condition or threshold, this can be the end of the OCV tracking process. The processor can save, in memory, the OCV measurement, the timestamp of this measurement, calculate the total relaxation time from the time of the 1st OCV measurement, and exit the tracking logic.

If the latest calculated dv/dt doesn't meet block 910, 914, and 918 logic, the monitoring interval will remain the same, and only capture OCV measurements and the corresponding timestamps if the latest dv/dt drop to half of its previous dv/dt value. The logic is then loop back to block 910 to capture a new OCV after the monitoring interval and calculate a new dv/dt for the next checking loop.

At block 926 the processor can determine if a present dv/dt is less than or equal to half of the reference dv/dt. If the present dv/dt is not less than or equal to half of the reference dv/dt as determined by the processor, then the process can return to block 908. If the present dv/dt is less than or equal to half of the reference dv/dt as determined by the processor, then the process can proceed to block 928. In block 928 the OCV can be saved in memory by the processor and a timestamp can be saved in memory by the processor, then the process can proceed to block 930. At block 930 the processor can update the reference dv/dt to a present dv/dt value, then the process can proceed to block 908.

It is understood that the specific order or hierarchy of blocks in the processes/flowcharts disclosed is an illustration of exemplary approaches. Based upon design preferences, it is understood that the specific order or hierarchy of blocks in the processes/flowcharts may be rearranged. Further, some blocks may be combined or omitted. The accompanying method claims present elements of the various blocks in a sample order and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

What is claimed is:

1. A method of autonomously capturing open cell voltage (OCV) trends of a battery for an electric vehicle, comprising:
receiving, by a radio node of the battery and from a radio manager associated with a controller, a command to begin an OCV monitoring process;
recording an initial OCV measurement;
determining if a time period measurement interval has been reached and, if the time period measurement interval has been reached, taking an OCV measurement and determining if an OCV rate of change between OCV measurements is less than a configured threshold.

2. The method of claim 1, wherein the battery is installed in a vehicle and the radio node is a low power radio node.

3. The method of claim 2, wherein taking the OCV measurement occurs when external power is removed by a key-off of the electric vehicle when the period measurement interval is a first monitoring interval.

4. The method of claim 2, wherein taking the OCV measurement occurs according to a preconfigured threshold for the monitoring interval when the period measurement interval is a second monitoring interval.

5. The method of claim 4, wherein taking the OCV measurement occurs when the period measurement interval is a third monitoring interval in a fully relaxed mode.

6. The method of claim 5, wherein the period measurement interval is a fourth monitoring interval that corresponds to a fully relaxed battery.

7. The method of claim 2, further comprising:
transmitting, by the radio node and based on a read procedure of the controller, OCV trend data when the vehicle is turned on.

8. The method of claim 2, wherein if the period measurement interval has not been reached, the method further comprises:
waiting for a period of time before determining if a measurement interval has been reached.

9. The method of claim 2, wherein if the OCV rate of change is not less than the configured threshold, the method further comprises:
determining if a next period measurement interval or part of a period measurement interval of a plurality of measurement intervals has been reached.

10. The method of claim 9, wherein each of the plurality of period measurement intervals is adaptive and is based on a measured change in OCV over time.

11. The method of claim 2, wherein if the OCV rate of change is less than the configured threshold,
recording the OCV measurement and an associated time;
updating the configured threshold based on a rate of change; and
updating the measurement interval.

12. The method of claim 11, further comprising:
determining if the updated measurement threshold has been reached.

13. The method of claim 1, further comprising:
recording a cell temperature associated with the OCV measurement.

14. The method of claim 1, wherein the OCV measurements occur prior to installation of the battery into a vehicle.

15. The method of claim 1, wherein the period measurement interval is preconfigured for different regions of a battery relaxation process.

16. A system for autonomously capturing open cell voltage (OCV) trends of a battery, comprising:
a host comprising:
a controller; and
a wireless communications manager; and
an OCV battery monitoring subsystem, comprising:
a wireless communication node;
one or more OCV memories;
one or more battery monitoring circuits; and
one or more cell stacks, wherein each of the one or more battery monitoring circuits is coupled with one or more cell stacks,
wherein the controller is configured to transmit a command to begin an OCV monitoring process via the wireless communications manager to the wireless communications node that causes the wireless communications node to execute the OCV monitoring process.

17. The system of claim 16, wherein the OCV monitoring process determines if an OCV rate of change is less than a configured threshold based on OCV measurements taken by the one or more battery monitoring circuits and stored in the one or more OCV memories.

18. The system of claim 17, wherein the OCV measurements are taken at intervals based on an expected OCV state.

19. The system of claim 18, wherein the intervals during a relaxation state are longer than during a pre-relaxation state.

20. The system of claim 16, wherein the OCV monitoring process comprises the wireless communications node waking up via pre-configured intervals and waking up one or more of the battery monitoring circuits to make OCV measurements.

21. An apparatus for autonomously capturing open cell voltage (OCV) trends of a battery, comprising:
a wireless communication node;
one or more OCV memories;
one or more battery monitoring circuits; and
one or more cell stacks, wherein each of the one or more battery monitoring circuits is coupled with one or more cell stacks,
wherein, upon wirelessly receiving a command from a host controller, the wireless communications node is configured to execute an OCV monitoring process that causes the wireless communications node to wake up at pre-configured intervals, wake up one or more of the battery monitoring circuits to make OCV measurements, and store the OCV measurements in the one or more OCV memories.
